(19) United States
(12) Patent Application Publication
(10) Pub. No.: US 2009/0160014 A1
(43) Pub. Date: Jun. 25, 2009

(54) SEMICONDUCTOR DEVICE AND METHOD FOR MANUFACTURING THE SAME

(76) Inventor: Dae-Kyeun Kim, Yongin-si (KR)

Correspondence Address: SHERR & VAUGHN, PLLC, 620 HERNDON PARKWAY, SUITE 200, HERNDON, VA, 20170, US

(21) Appl. No.: 12/188,173

(22) Filed: Aug. 7, 2008

(30) Foreign Application Priority Data
Dec. 24, 2007 (KR) 10-2007-0136207

(51) Int. Cl. H01L 29/00; H01L 21/76

(52) U.S. Cl. 257/510; 438/425; 257/E21.546

(57) ABSTRACT

A semiconductor device and/or a method for manufacturing a semiconductor device. A method may include at least one of the following: Forming a first semiconductor layer over a semiconductor substrate. Forming a second semiconductor layer over the first semiconductor layer. Forming a trench through the first and second semiconductor layers. The trench may be fulled with an isolation film. The portion of the trench in the first semiconductor layer may have a width larger than a minimum width of the portion of the trench in the second semiconductor layer.

The present application claims priority under 35 U.S.C. 119 to Korean Patent Application No. 10-2007-0136207 (filed on Dec. 24, 2007), which is hereby incorporated by reference in its entirety.

### BACKGROUND

It may be desirable to maximize and/or optimize integration of semiconductor devices, which may be made possible by manufacturing techniques. With maximized and/or optimized integration, there may be many applications for manufactured semiconductor devices. Some manufacturing techniques relate to minimizing the size of an isolation film that isolates elements from each other.

A local oxidation of silicon (LOCOS) process may be used as an isolation technique. A LOCOS process may be advantagous since a silicon wafer may be thermally oxidized using a nitride film as a mask. It may be possible to simplify the overall process, which may reduce complications associated with stress of an oxide film forming and enhancing the quality of the oxide film.

However, when a LOCOS process is used in an area occupied by an isolation region (e.g. which may be relatively large), there may be limitations in manufacturing small patterns (e.g. fine patterns). Further, when using a LOCOS process, a bird's beak may occur. Forming a shallow trench isolation (STI) may be one solution to improving isolation.

When forming a STI, a narrow and deep trench may be formed using a dry etching technique (e.g. reactive ion etching or plasma etching) and the trench may be filled with an oxide film. An insulating material may be filled in a trench formed in a silicon wafer, which may minimize complications associated with a bird's beak. Also, because a planarized surface may be formed in the process of filling the insulating material in the trench, the area occupied by the isolation region may be smaller, which may improve the ability to form fine features.

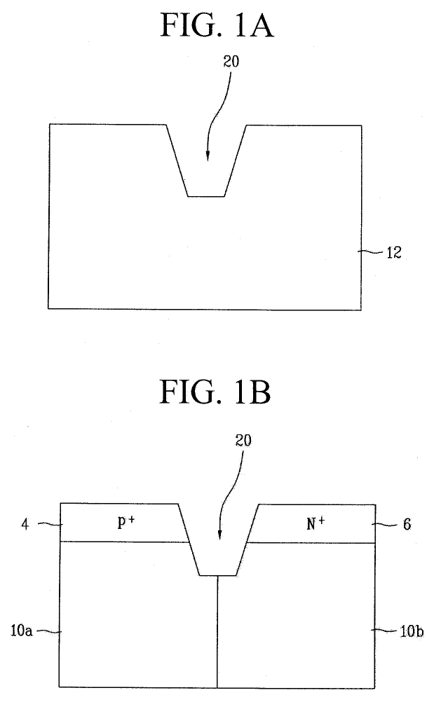

Example FIGS. 1A and 1B are sectional views illustrating a semiconductor device manufacturing method. As illustrated in FIG. 1A, a photoresist is coated over semiconductor substrate 12. A photolithography process and/or an etching process are then implemented on semiconductor substrate 12 to form a trench 20 (e.g. as an isolation element between semiconductor elements).

As illustrated in FIG. 1B, N-well region 10a and P-well region 10b are formed around opposite sides of trench 20. N⁺ impurity ions may be implanted in P-well region 10b, to form N⁺ source/drain region 6 (e.g. a pick-up region). P⁺ impurity ions may be implanted in N-well region 10a to form a P⁺ source/drain region 4.

An insulating film may be deposited in trench 20. If trench 20 is relatively deep, voids may form at an upper portion of the trench 20 in the insulating film before the insulating film completely fills trench 20. In order to solve this problem, trench 20 may be formed to have a relatively low depth. However, a trench with a relatively low depth may have limited ability to isolate, resulting in unnecessary current leakage. Accordingly, there are limitations in trench 20 having a relatively low depth.

### SUMMARY

Embodiments relate to a semiconductor device and/or a method of manufacturing a semiconductor device. Embodiments may minimize leakage current and/or maximize isolation characteristics.

Embodiments relate to a semiconductor device that may include at least one of the following: A first semiconductor layer formed on and/or over a semiconductor substrate. A second semiconductor layer formed on and/or over the first semiconductor layer. A trench formed through the first semiconductor layer and the second semiconductor layers. The trench may be filled with an isolation film. The portion of the trench formed in the first semiconductor layer may be wider than a minimum width of the portion of the trench formed in the second semiconductor layer.

Embodiments relate to a method of manufacturing a semiconductor device that may include at least one of the following: Forming a first semiconductor layer on and/or over a semiconductor substrate. Forming a second semiconductor layer on and/or over the first semiconductor layer. Forming a trench (e.g. to be filled with an isolation film) through the first semiconductor layer and the second semiconductor layer. The portion of the trench formed in the first semiconductor layer may have a larger width than a minimum width of the portion of the trench formed in the second semiconductor layer.

### DRAWINGS

Example FIGS. 1A and 1B illustrate a semiconductor device and a method of manufacturing a semiconductor device.

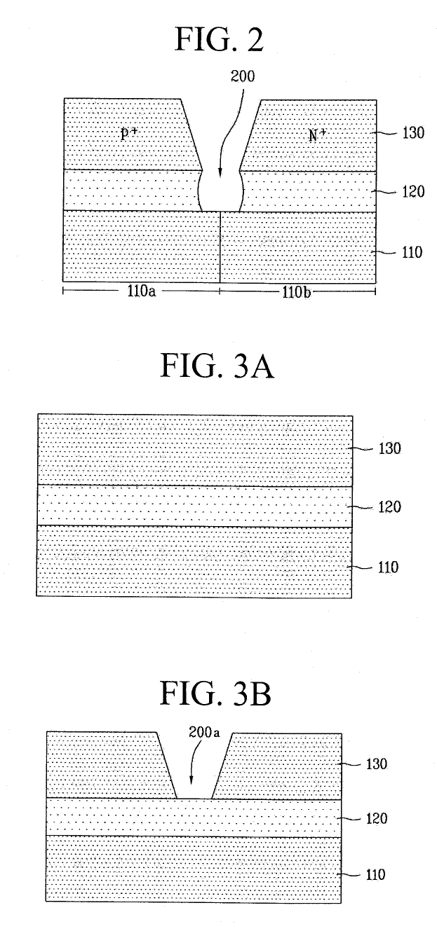

Example FIG. 2 illustrates a sectional view of a semiconductor device, in accordance with embodiments.

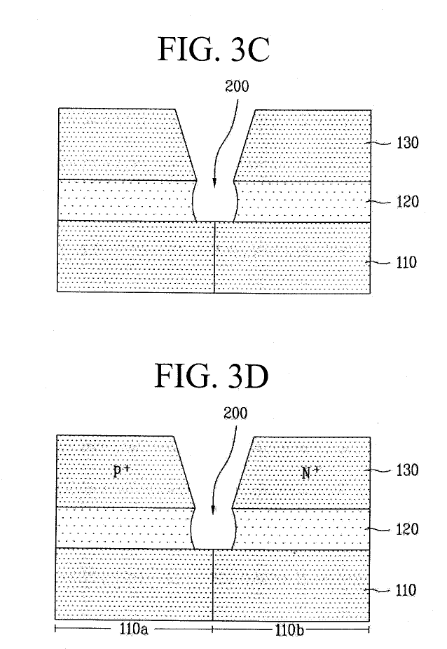

Example FIGS. 3A to 3D are sectional views illustrating a method of manufacturing a semiconductor device, in accordance with embodiments.

### DESCRIPTION

Example FIG. 2 illustrates a sectional view of a semiconductor device, according to embodiments. As illustrated in FIG. 2, a semiconductor device includes semiconductor silicon substrate 110. First semiconductor layer 120 may be formed on and/or over semiconductor substrate 110. Second semiconductor layer 130 may be formed on and/or over first semiconductor layer 120. Trench 200 may be formed through first semiconductor layer 120 and second semiconductor layer 130. In a subsequent process an insulating material may be filled in the trench 200 to form an isolation film. In embodiments, impurity ions (e.g. boron (B) ions) may be implanted in semiconductor silicon substrate 110, first semiconductor layer 120, and second semiconductor layers 130.

First semiconductor layer 120 and second semiconductor layers 130 may have a thickness ratio of about 1:3 or 3:1. First semiconductor layer 120 and second semiconductor layers 130 may have a thickness between approximately 1,500 Å and 4,000 Å. The width of the portion of trench 200 in the first semiconductor layer 120 may be larger than the minimum width of the portion of trench 200 in second semiconductor layer 130, in accordance with embodiments.

N-well region 110a and P-well region 110b may be formed in semiconductor silicon substrate 110 and/or first semiconductor layer 120 around opposite sides of trench 20. P type impurity ions may be implanted in N-well region 110a and N type impurity ions are implanted in P-well region 110b to form source/drain regions in N-well region 110a and P-well region 110b.

Since the trench width in first semiconductor layer 120 is relatively large, a leakage current path may be lengthened between elements, in accordance with embodiments. Accordingly, even if the depth of the isolation film in trench 200 is relatively low, desirable isolation characteristics and/or leakage current characteristics may be achieved, in accordance with embodiments.

Example FIGS. 3A to 3D are sectional views illustrating a method of manufacturing a semiconductor device, in accordance with the embodiments. As illustrated in Example 3A, first semiconductor layer 120 may be formed on and/or over semiconductor silicon substrate 110. Second semiconductor layer 130 may be formed on and/or over first semiconductor layer 120. In embodiments, first semiconductor layer 120 and second semiconductor layer 130 comprises at least one silicon material.

Impurity ions (e.g. boron (B) ions) may be implanted in semiconductor silicon substrate 110, first semiconductor layer 120, and second semiconductor layers 130. Semiconductor silicon substrate 110 may have a doping concentration between approximately 10¹⁵ ions/cm² and 10¹⁹ ions/cm², in accordance with embodiments. First semiconductor layer 120 may have a doping concentration between approximately 10¹⁰ ions/cm² and 10²² ions/cm², in accordance with embodiments. Second semiconductor layer 130 may have the same or different doping concentration as first semiconductor layer 120, in accordance with embodiments. The doping concentration of second semiconductor layer 130 may be the same or different as semiconductor silicon substrate 110, in accordance with embodiments.

Although, in some embodiments, first semiconductor layer 120 and second semiconductor layer 130 may be sequentially formed on and/or over semiconductor silicon substrate 10, they may be formed in different ways in different embodiments. For example, in embodiments, first semiconductor layer 120 may be formed by cutting a single silicon substrate into two sections (e.g. semiconductor silicon substrate 110 and second semiconductor layer 130). An intermediate semiconductor layer (e.g. first semiconductor layer 120) may be formed between semiconductor silicon substrate 110 and second semiconductor layer 130, in accordance with embodiments.

Example FIG. 3B illustrates trench 200a formed in second semiconductor layer 130, in accordance with embodiments. In embodiments, trench 200a may be formed by coating a photoresist on and/or over second semiconductor layer 130 and then using the photoresist as a mask to form trench 200a (e.g. using a photolithography process and/or an etching process).

As illustrated in example FIG. 3C, first semiconductor layer 120 may be etched to form trench 200, in accordance with embodiments. In embodiments where second semiconductor layer 130 has a silicon doping concentration different from first semiconductor layer 120, an etch rate through second semiconductor layer 130 may be lower than first semiconductor layer 120. With a lower etch rate through second semiconductor layer 130, the width of a portion of trench 200 in first semiconductor layer 120 may be larger than the minimum width of a portion of trench 200 in second semiconductor layer 130, in accordance with embodiments. In a subsequent process, an insulating material may be filled in trench 200 to form an isolation film. The etching ratio between first semiconductor layer 120 and second semiconductor layer 130 (e.g. for formation of trench 200) may be varied in accordance with the respective silicon doping concentrations of the first semiconductor layer 120 and second semiconductor layer 130, in accordance with embodiments.

As illustrated in example FIG. 3D, a well implant process may be carried out around opposite sides of trench 200, to form N-well region 110a and P-well region 110b, in accordance with embodiments. In embodiments, N-well region 110a and P-well region 110b may be formed by coating a photoresist on and/or over second semiconductor layer 130 and alternately implanting positive (+) or negative (−) impurity ions. In order to form source/drain regions in N-well region 110a and P-well region 110b, P type impurity ions may be implanted in N-well region 110a, and N type impurity ions may be implanted in the P-well region 110b.

In embodiments, the width of the portion of trench 200 in the first semiconductor layer may be larger than the minimum width of the portion of trench 200 in the second semiconductor layer 130. Accordingly, in embodiments, the leakage current path between elements may be relatively long. Accordingly, even if the depth of an isolation film is relatively low in trench 200, leakage current characteristics and/or device isolation characteristics may be optimized.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a first semiconductor layer formed over a semiconductor substrate;
a second semiconductor layer formed over said first semiconductor layer; and
a trench formed through the first semiconductor layer and the second semiconductor layer,
wherein the trench is configured to be filled with an isolation film, and
wherein a portion of the trench formed in the first semiconductor layer is wider than the minimum width of a portion of the trench formed in the second semiconductor layer.

2. The apparatus of claim 1, wherein the first semiconductor layer has a thickness ratio of approximately 1:3 or approximately 3:1.

3. The apparatus of claim 1, wherein the second semiconductor layer has a thickness ratio of approximately 1:3 or approximately 3:1.

4. The apparatus of claim 1, wherein the first semiconductor layer has a thickness between approximately 1,500 Å and 4,000 Å.

5. The apparatus of claim 1, wherein the second semiconductor layer has a thickness between approximately 1,500 Å and 4,000 Å.

6. The apparatus of claim 1, wherein the second semiconductor layer has an impurity doping concentration which is approximately the same as an impurity doping concentration of the semiconductor substrate.

7. The apparatus of claim 1, wherein the second semiconductor layer has an impurity doping concentration different from an impurity doping concentration of the semiconductor substrate.

8. The apparatus of claim 1, wherein the semiconductor substrate has an impurity doping concentration between approximately 10¹⁵ ions/cm² and 10¹⁹ ions/cm².

9. The apparatus of claim 1, wherein said first semiconductor layer has an impurity doping concentration between approximately 10¹⁰ ions/cm² and 10²² ions/cm².

10. The apparatus of claim 1, wherein the first semiconductor layer has a higher etching rate than the second semiconductor layer.

11. A method comprising:
forming a first semiconductor layer over a semiconductor substrate;
forming a second semiconductor layer over the first semiconductor layer; and
forming a trench through the first semiconductor layer and the second semiconductor layer,
wherein the trench formed in the first semiconductor layer is wider than a minimum width of the trench formed in the second semiconductor layer, and
the trench is configured to be filled with an isolation film

12. The method according to claim 11, wherein the first semiconductor layer has a thickness ratio of approximately 1:3 or approximately 3:1.

13. The method according to claim 11, wherein the second semiconductor layer has a thickness ratio of approximately 1:3 or approximately 3:1.

14. The method according to claim 11, wherein the first semiconductor layer has a thickness between approximately 1,500 Å and 4,000 Å.

15. The method according to claim 11, wherein the second semiconductor layer has a thickness between approximately 1,500 Å and 4,000 Å.

16. The method according to claim 11, wherein the semiconductor substrate has an impurity doping concentration between approximately 10¹⁵ ions/cm² and 10¹⁹ ions/cm².

17. The method according to claim 11, wherein said first semiconductor layer has an impurity doping concentration between approximately 10¹⁰ ions/cm² and 10²² ions/cm².

18. The method according to claim 11, wherein the first semiconductor layer has a higher etching rate than the second semiconductor layer.

19. The method according to claim 11, wherein the second semiconductor layer has substantially the same impurity doping concentration as the semiconductor substrate.

20. The method according to claim 11, wherein the second semiconductor layer has a different impurity doping concentration than the semiconductor substrate.
